(19) United States
(12) Patent Application Publication
(10) Pub. No.: US 2025/0201628 A1
(43) Pub. Date: Jun. 19, 2025

(54) METHODS FOR DEPOSITING GAP FILLING FLUIDS AND RELATED SYSTEMS AND DEVICES

(71) Applicant: ASM IP Holding B.V., Almere (NL)

(72) Inventors: Timothee Blanquart, Oud-Heverlee (BE); Viljami Pore, Helsinki (FI); René Vervuurt, Leuven (BE); Jihee Jeon, Leuven (BE)

(21) Appl. No.: 18/985,474

(22) Filed: Dec. 18, 2024

Related U.S. Application Data
(63) Continuation of application No. 17/467,590, filed on Sep. 7, 2021, now Pat. No. 12,211,742.
(60) Provisional application No. 63/076,678, filed on Sep. 10, 2020.

(51) Int. Cl. H01L 21/768; C23C 16/34; C23C 16/455; C23C 16/50; C23C 16/52; H01L 21/02

(52) U.S. Cl. CPC H01L 21/76837; C23C 16/342; C23C 16/4554; C23C 16/45553; C23C 16/50; C23C 16/52; H01L 21/02205; H01L 21/0228

(57) ABSTRACT

Methods and systems for manufacturing a structure comprising a substrate. The substrate comprises plurality of recesses. The recesses are at least partially filled with a gap filling fluid. The gap filling fluid comprises boron, nitrogen, and hydrogen.

### CROSS-REFERENCE TO RELATED APPLICATIONS

This application is a continuation of, and claims priority to, U.S. patent application Ser. No. 17/467,590 filed Sep. 7, 2021 titled METHODS FOR DEPOSITING GAP FILLING FLUIDS AND RELATED SYSTEMS AND DEVICES; which claims priority to U.S. Provisional Patent Application Ser. No. 63/076,678 filed Sep. 10, 2020 titled METHODS FOR DEPOSITING GAP FILLING FLUIDS AND RELATED SYSTEMS AND DEVICES, the disclosure of which is hereby incorporated by reference in its entirety.

### FIELD OF INVENTION

The present disclosure generally relates to methods and systems suitable for forming electronic devices. More particularly, the disclosure relates to methods and systems that can be used for depositing a material in gaps, trenches, and the like, for example by thermally activated or by plasma-assisted deposition processes.

### BACKGROUND OF THE DISCLOSURE

The scaling of semiconductor devices has led to significant improvements in speed and density of integrated circuits. However, with miniaturization of wiring pitch of large scale integration devices, void-free filling of high aspect ratio trenches (e.g., trenches having an aspect ratio of three or higher) becomes increasingly difficult due to limitations of existing deposition processes. Therefore, there remains a need for processes that efficiently fill high aspect ratio features, e.g., gaps such as trenches on semiconductor substrates.

The following prior art document is made of record: U.S. Pat. No. 9,412,581B2. The '258 patent describes a low-K dielectric gapfill by flowable deposition using a silicon-carbon-oxygen layer.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to gap filling methods, to structures and devices formed using such methods, and to apparatus for performing the methods and/or for forming the structure and/or devices. The ways in which various embodiments of the present disclosure address drawbacks of prior methods and systems are discussed in more detail below.

Described herein is a method of filling a gap. Exemplary methods include introducing in a reaction chamber a substrate provided with a gap, introducing a precursor into the reaction chamber, introducing a co-reactant into the reaction chamber, and forming plasma in the reaction chamber. In some cases, the precursor consists of boron, nitrogen, hydrogen, and optionally one or more halogens. The co-reactant can be selected from a nitrogen-containing gas, a hydrogen-containing gas, a boron-containing gas, a noble gas, and mixtures thereof. The precursor and the co-reactant react to form a gap filling fluid that at least partially fills the gap, the gap filling fluid comprising boron, nitrogen, and hydrogen.

In some embodiments, the precursor can be represented by a chemical formula according to formula (i)

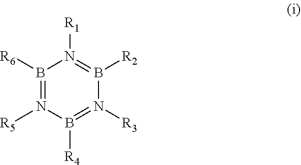

wherein R₁, R₂, R₃, R₄, R₅, and R₆ are independently selected from H, NH₂, a halogen, or one or more alkyl groups (e.g., C₁-C₄ alkyl groups).

In some embodiments, at least one (e.g., 1-6) of R₁, R₂, R₃, R₄, R₅, and R₆ is F, Cl, Br, and/or I.

In some embodiments, the precursor is borazine.

In some embodiments, the precursor is or includes diborane.

In some embodiments, the reaction chamber is maintained at a temperature below 80° C.

In some embodiments, the co-reactant is selected from Ar, He, a mixture of Ar and H₂, and a mixture of He and H₂.

In some embodiments, the co-reactant is selected from Ar, He, N₂, and ammonia.

In some embodiments, the method comprises a cyclic deposition process, wherein the co-reactant is provided continuously, wherein the precursor is provided in a plurality of precursor pulses, wherein the plasma is provided in a plurality of plasma pulses, and, wherein individual precursor pulses and individual plasma pulses are separated (e.g., by purge steps).

In some embodiments, no gasses other than the precursor, the co-reactant, ammonia, nitrogen, and a noble gas are introduced into the reaction chamber while introducing the precursor, the co-reactant and the plasma into the reaction chamber.

In some embodiments, a dopant precursor is introduced to the reaction chamber. The dopant precursor can be introduced, for example, while introducing the precursor, the co-reactant, and/or during formation of the plasma in the reaction chamber. Exemplary dopant precursors include Si or C. Particular examples include alkyl compounds, silanes, and alkylsilyl compounds.

In some embodiments, introducing the precursor and the co-reactant occurs simultaneously, or at substantially the same time. In some cases, the precursor and the co-reactant are provided to the reaction chamber at the same time.

Further described herein is a method of filling a gap comprising: introducing in a reaction chamber comprising a susceptor and walls, a substrate provided with a gap, and placing the substrate on the susceptor; introducing an inert gas into the reaction chamber; introducing a precursor into the reaction chamber, the precursor consisting of boron, nitrogen, and hydrogen; the precursor having an activation temperature above which the precursor undergoes a spontaneous polymerization reaction, and below which the precursor is substantially stable; and, maintaining the susceptor at a temperature which is higher than the activation temperature, and maintaining the walls at a temperature which is lower than the activation temperature; whereby the precursor forms a gap filling fluid that at least partially fills the gap, the gap filling fluid comprising boron, nitrogen, and hydrogen.

In some embodiments, the precursor is represented by formula (i), borazine, or diborane.

In some embodiments, the precursor is introduced into the reaction chamber by means of a carrier gas.

In some embodiments, the carrier gas is selected from the list consisting of Ar, He, and N₂.

In some embodiments, the method further comprises providing a co-reactant to the reaction chamber. The co-reactant can include any co-reactant noted herein.

In some cases, the method further includes providing a dopant precursor to the reaction chamber.

In some embodiments, the activation temperature is 80° C.

In some embodiments, the reaction chamber is comprised in a system, the system further comprising a plurality of gas lines, a showerhead, and a pump, wherein the gas lines, the showerhead, and the pump are maintained at a temperature lower than 70° C.

In some embodiments, the reaction chamber is comprised in a system, the system further comprising a cold trap, wherein the cold trap is maintained at a temperature which is lower than a boiling temperature of the precursor.

In some embodiments, the reaction chamber is at a pressure of at least 500 Pa to at most 1500 Pa.

In some embodiments, the reaction chamber is at a pressure of at least 600 Pa or 700 Pa to at most 1200 Pa.

In some embodiments, the substrate comprises a semiconductor.

In some embodiments, the method includes entirely filling the gap with a gap filling fluid.

In some embodiments, the method comprises curing the gap filling fluid.

In some embodiments, the step of curing involves the use of a direct plasma and the method for filling a gap comprises a plurality of cycles in which gap filling fluid deposition and plasma treatment steps are alternated.

In some embodiments, the step of curing involves the use of an indirect plasma after the gap has been filled with the gap filling fluid.

In some embodiments, the step of curing involves the use of a noble gas plasma.

In some embodiments, the step of curing involves the use of a micro pulsed plasma involving the sequential application of a plurality plasma on and plasma off pulses.

In some embodiments, the substrate is a 300 mm silicon wafer, and wherein a plasma gas flow rate of at least 5.0 slm (standard liters per minute) is maintained during the micro pulsed plasma.

Further described herein is a system configured to perform the method according to the present disclosure.

Further described herein is a system comprising: one or more reaction chambers; a gas injection system fluidly coupled to at least one of the one or more reaction chambers; a first gas source for introducing a precursor and optionally a carrier gas in the reaction chamber; a second gas source for introducing a mixture of one or more further gasses into the reaction chamber; an exhaust; and a controller, wherein the controller is configured to control gas flow into the gas injection system and for causing the system to carry out a method according to the present disclosure.

In some embodiments, the system further comprises a plasma generator for generating a plasma in the reaction chamber, wherein the controller is further configured for causing the plasma generator to provide a plasma in the reaction chamber in accordance with the methods described herein.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 is a schematic representation of a plasma-enhanced atomic layer deposition (PEALD) apparatus suitable for depositing a structure and/or for performing a method in accordance with at least one embodiment of the present disclosure.

FIG. 2 illustrates a schematic representation of a precursor supply system using a flow-pass system (FPS) usable in accordance with at least one embodiment of the present disclosure.

FIG. 3 illustrates a timing sequence in accordance with at least one embodiment of the present disclosure.

FIG. 4 illustrates a structure in accordance with at least one embodiment of the present disclosure.

FIGS. 5A and 5B illustrate a perforated plate for use in accordance with at least one embodiment of the present disclosure.

FIGS. 6A-6C illustrate a multi-channel perforated plate for use in accordance with at least one embodiment of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a rare gas. The terms “rare gas” and “noble gas” as used herein may be used interchangeably. In some cases, the term “precursor” can refer to a compound that participates in the chemical reaction that produces another compound, and particularly to a compound that constitutes a film matrix or a main skeleton of a film, or that is incorporated in a film as a constituent part thereof; the term “reactant” may be used interchangeably with the term precursor.

As used herein, the term “co-reactant” refers to a gas which can react and/or interact with a precursor in order to form a flowable gap fill layer as described herein. The co-reactant may activate precursor oligomerization. The co-reactant may be a catalyst. The co-reactant does not necessarily have to be incorporated in the gap filling fluid that is formed, though the co-reactant does interact with the precursor during formation of the gap filling fluid. Possible co-reactants include noble gasses such as He and Ar, as well as other gasses such as N₂, H₂, and NH₃. Alternative expressions for the term “co-reactant” as used herein may include “reactant,” “gas mixture,” “one or more further gasses,” and “gas mixture comprising one or more further gasses.”

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as a Group II-VI or Group Ill-V semiconductor, and can include one or more layers overlying or underlying the bulk material.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

As used herein, the term “comprising” indicates that certain features are included, but that it does not exclude the presence of other features, as long as they do not render the claim or embodiment unworkable. In some embodiments, the term “comprising” includes “consisting” and “consisting essentially of” in some embodiments.

As used herein, the term “consisting” indicates that no further features are present in the apparatus/method/product apart from the ones following said wording. When the term “consisting” is used referring to a chemical compound, it indicates that the chemical compound only contains the components which are listed.

As used herein, the term “gap filling fluid,” also referred to as “flowable gap fill,” may refer to an oligomer-containing composition of matter which is liquid under the conditions under which is deposited on a substrate and which has the capability to cross link and form a solid film.

In this disclosure, the term “filling capability” refers to a capability of filling a gap substantially without voids (e.g., no void having a size of approximately 1 nm or greater in diameter) and seams (e.g., no seam having a length of approximately 5 nm or greater), wherein seamless/void less bottom-up growth of a layer is observed. The growth at a bottom of a gap may be at least approximately 1.5 times faster than growth on sidewalls of the gap and on a top surface having the gap. A film having filling capability is referred to as “flowable film” or “viscous film.” The flowable or viscous behavior of a film is often manifested as a concave surface at a bottom of a trench.

In this disclosure, a recess between adjacent protruding structures and any other recess pattern may be referred to as a “trench.” That is, a trench may refer to any recess pattern including a hole/via. A trench can have, in some embodiments, a width of about 5 nm to about 100 nm, and typically about 10 nm to about 20 nm. When a trench has a length that is substantially the same as its width, it can be referred to as a hole or a via. Holes or vias typically have a width of about 20 nm to about 100 nm. In some embodiments, a trench has a depth of about 30 nm to about 100 nm, and typically of about 40 nm to about 60 nm. In some embodiments, a trench has an aspect ratio of about 2 to about 15, and typically of about 3 to about 10. The dimensions of the trench may vary depending on process conditions, film composition, intended application, etc.

As used herein, the term “height” may refer to the extent of a feature in a direction perpendicular to the surface of the substrate that comprises the feature in question.

As used herein, the term “width” may refer to the extent of a feature in a direction in a plane parallel to the surface of the substrate that comprises the feature in question.

As used herein, the term “length” may refer to the extent of a feature in a direction in a plane parallel to the surface of the substrate that comprises the feature in question. The directions in which the “width” and the “length” are measured are mutually perpendicular. It shall be understood that all dimensions, including length, width, and height of a structure, can be measured using routine techniques such as scanning transmission electron microscopy (STEM).

Described herein are methods of filling a gap. The methods are particularly useful for filling a gap with hydrogenated amorphous boron nitride by performing a process that comprises oligomerizing a volatile precursor to form a flowable phase, i.e., a gap filling fluid. Both thermal methods and plasma-enhanced methods are described.

The gap filling fluid can be applied to various semiconductor devices including, but not limited to, cell isolation in 3D cross point memory devices, self-aligned via, dummy gate, reverse tone patterning, PC RAM isolation, cut hard mask, and DRAM storage node contact (SNC) isolation. In one embodiment, the gap filling fluid is used as a low-k dielectric.

In some embodiments, the gap is entirely filled with the gap filling fluid. It shall be understood that the gap filling fluid can be described as a viscous material, i.e., a viscous phase that is deposited on the substrate. The gap filling fluid is capable of flowing in a trench on the substrate. Suitable substrates include silicon wafers. As a result, the viscous material seamlessly fills the trench in a bottom-up way.

Flowable films may be temporarily obtained when a volatile precursor is polymerized by a plasma and deposited on a surface of a substrate, wherein gaseous precursor (e.g. monomer) is activated or fragmented by energy provided by plasma gas discharge so as to initiate polymerization, and when the resultant material is deposited on the surface of the substrate, the material shows temporarily flowable behavior. In some embodiments, the gap filling fluid formed by means of the presently described methods comprises a polyborazine oligomer. The polyborazine oligomer may be branched or linear. Suitably, the polyborazine oligomer comprises a plurality of oligomeric species, i.e., the gap filling fluid may comprise various different oligomers, both branched and linear.

In accordance with exemplary embodiments, when the deposition step is complete, the flowable film is no longer flowable but is solidified, and thus, a separate solidification process is not required. In other embodiments, the flowable film is densified and/or solidified after deposition, e.g., by means of a curing step such as a plasma cure. In accordance with further examples, after deposition and any solidification step, a capping layer is deposited.

The gap filling fluids that are deposited herein may comprise hydrogen. In some embodiments, the gap filling fluids that are deposited herein comprise between 0.1% and 30.0%, between 20.0% and 30.0%, between 10.0% and 20.0%, between 0.1% and 10.0%, or between 0.2% and 5.0%, or between 0.5% and 2.5%, or between 1.0% and 2.0% hydrogen, wherein all percentages are given in atomic percent. Hence, when, for example, a gap filling fluid is referred to as boron nitride (BN), the breath of the term “BN” is intended to encompass BN:H, i.e., BN comprising hydrogen, e.g. up to 30 atomic percent hydrogen. As discussed in more detail below, in some cases, the BN can include additional dopants, such as C and/or Si.

In one aspect, the presently described methods employ a plasma for filling a gap with a gap filling fluid, e.g., to form a low-k dielectric. Such methods comprise introducing a substrate into a reaction chamber. The substrate comprises a gap. The method further comprises introducing a precursor into the reaction chamber. The method further comprises introducing a co-reactant into the reaction chamber. The co-reactant may be suitably selected from a nitrogen-containing gas, a hydrogen-containing gas, a boron-containing gas, ammonia, a noble gas, and mixtures thereof. The method further comprises introducing or forming a plasma in the reaction chamber. Thus, the precursor and the co-reactant react to form a gap filling fluid that at least partially fills the gap. The thusly formed gap filling fluid comprises boron, nitrogen, and hydrogen. In some embodiments, the gap filling fluid essentially consists of boron, nitrogen, and hydrogen, alone or with a dopant (e.g., Si and/or C).

It shall be understood that the thusly formed gap filling fluid forms, once solidified, an amorphous and hydrogenated boron nitride layer. Also, it shall be understood that the co-reactant is not necessarily incorporated in the gap filling fluid which is deposited. For example, when a plasma gas comprising a noble gas such as argon is used as a co-reactant, the argon is not substantially incorporated in the gap filling fluid.

When the present methods employ a plasma for filling a gap with a gap filling fluid, the precursor consists of boron, nitrogen, hydrogen, and optionally one or more halogens. It shall be understood that the layers thus formed do not contain any appreciable carbon, which can beneficiously impact such properties as the dielectric constant, and the resistivity of the thusly formed layer. When the layer is used as a low-k dielectric, for example, the resulting structures can advantageously offer low leakage current.

In some embodiments, the precursor consists of boron, nitrogen, and hydrogen, which may yield a filled gap consisting substantially of boron, nitrogen, and hydrogen, which may offer especially high resistivity, and when incorporated in an electronic device such as an integrated circuit, especially low leakage current.

In some embodiments, the precursor consists of boron, nitrogen, hydrogen, and one or more halogens such as fluorine or chlorine. When a hydrogen-containing co-reactant is then used, the halogens may form a hydrogen halide, e.g., hydrogen fluoride or hydrogen chloride, which are volatile under conditions commonly present in the reaction chamber. Thus, when a halogen-containing precursor is used in combination with a hydrogen-containing co-reactant, gap filling fluids may be formed which are substantially free from halogens. Accordingly, a filled gap may be produced consisting substantially of boron, nitrogen, and hydrogen, which may offer especially high resistivity, and when incorporated in an electronic device such as an integrated circuit, especially low leakage current.

In some embodiments, the precursor consists of boron, nitrogen, hydrogen, and one or more halogens such as fluorine or chlorine, and the co-reactant does not comprise hydrogen. Suitable co-reactants in these embodiments include N₂ and noble gasses such as He and Ar. In such embodiments, substantial amounts of halogens may be incorporated in the gap filling fluid. The inclusion of halogens such as fluorine or chlorine may advantageously lower the dielectric constant of the gap filling fluid.

In some embodiments, the precursor used when employing a plasma can be represented by a chemical formula according to formula (a)

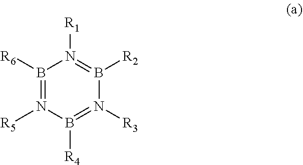

with R₁, R₂, R₃, R₄, R₅, and R₆ independently selected from H and a halogen. In some embodiments, at least one of R₁, R₂, R₃, R₄, R₅, and R₆ is F, Cl, Br, or I. In some cases, three of R1-R6 comprise a halogen (e.g., tribromoborazine, trichloroborazine). Alternatively, R₁, R₂, R₃, R₄, R₅, and R₆ may all be H. Accordingly, in some embodiments, the precursor is borazine. In accordance with further examples, one or more of R1-R6 can be a an alkyl group, such as a C1-C4 alkyl group. Particular exemplary alkyl groups include ethyl, propyl, and butyl groups (e.g., trimethylborazine and triethylborazine). Halogen and alkyl substituents may advantageously increase precursor stability. The presence of substituents can cause incorporation of impurities in the resulting film, which can be advantageous dopants or detrimental defects, depending on the application. In particular, haloborazine precursors can result in halogen-containing boron nitride films. Alkylborazine precursors can result in carbon-containing boron nitride films.

In accordance with other examples of the disclosure, the precursor can be or include diborane.

Suitably, the reactor chamber is maintained at a temperature which is lower than the temperature at which the precursor undergoes a spontaneous polymerization reaction. For example, when the precursor is borazine, the reaction chamber may be maintained at a temperature below 80° C. In some embodiments, the reaction chamber is maintained at a temperature below 60° C. In some embodiments, the reaction chamber is maintained at a temperature below 70° C. In some embodiments, the reaction chamber is maintained at a temperature below 90° C. In some embodiments, the reaction chamber is maintained at a temperature below 100° C.

In some embodiments, the co-reactant is selected from Ar, He, a mixture of Ar and H₂, and a mixture of He and H₂. In some embodiments, the co-reactant is selected from a noble gas, and a mixture of a noble gas and H₂.

In some embodiments, the co-reactant is selected from Ar, He, and N₂. In some embodiments, the co-reactant is selected from a noble gas and N₂.

In some embodiments, the co-reactant comprises ammonia.

In some embodiments, the co-reactant is supplied to the reaction chamber as a carrier gas, i.e., as a gas that entrains the precursor, and/or as an additional gas. In some embodiments, the carrier gas is provided at a flow rate of at least 0.2 to at most 4.0 slpm (standard liters per minute), or from at least 0.3 to at most 1.5 slpm, or from at least 0.4 to at most 1.0 slpm, or from at least 0.5 to at most 0.7 slpm.

In accordance with further examples of the disclosure, one or more dopant precursors are provided to the reaction chamber during a deposition method. The dopant precursor(s) can provide dopant(s) during the deposition process. The dopant(s) may mitigate transformation of deposited amorphous BN into crystalline or polycrystalline BN—e.g., during a solidification or treatment step. The dopant precursor(s) can be separately introduced into the reaction chamber during a deposition method or can be introduced with one or more of the precursor and the co-reactant.

Exemplary dopant precursors include silicon and/or carbon. By way of examples, the dopant precursors can be or include a silane, an alkyl compound (e.g., a C1-4 alkyl compound), an alkylsilyl compound (e.g., having 1-3 silicon atoms with C1-C2 functional groups), such as silane, disilane, trisilane, methane, ethane, propane, butane, methylsilane, ethylsilane, or the like.

In preferred embodiments, the present methods involve employing a plurality of deposition cycles. Each deposition cycle comprises providing the precursor in a precursor pulse, and providing the RF power in a further plasma pulse, wherein the two pulses do not overlap. Preferably, the precursor pulses and the plasma pulses are separated by purge gas pulses. Thus, in some embodiments, the method for filling a gap comprises a plurality of deposition cycles comprising alternating pulses in which precursor is provided, and pulses in which RF power is provided for generating a plasma. Preferably, these precursor pulses and plasma pulses are separated by purge pulses in which a purge gas is flowed. In the following paragraphs, process conditions are given for a reaction chamber volume of 1 liter and for 300 mm wafers. The skilled person understands that these values can be readily extended to other reaction chamber volumes and wafer sizes.

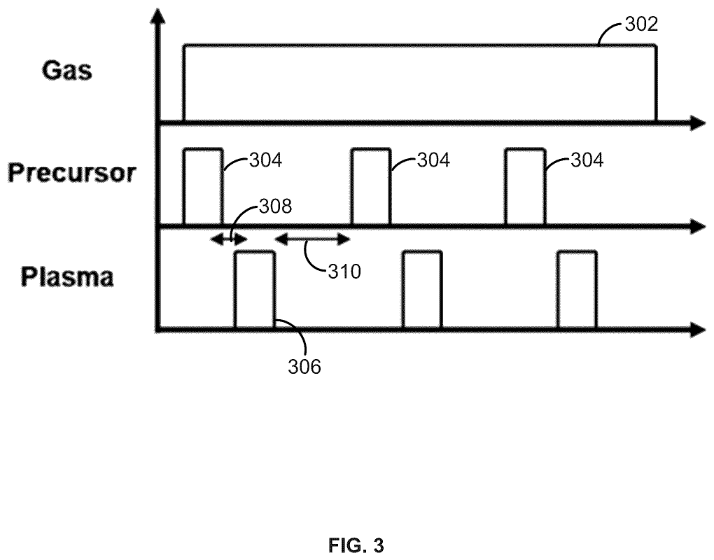

FIG. 3 illustrates a timing sequence 300 suitable for use in accordance with examples of the disclosure. Timing sequence 300 includes a gas pulse 302, precursor pulses 304, and plasma power pulses 306. During gas pulse 302, a co-reactant and optionally a carrier gas is provided to the reaction chamber. During this step or a portion thereof, a dopant precursor can also be provided to the reaction chamber. During precursor pulse 304, a precursor is provided to the reaction chamber; during this step or a portion thereof, a dopant precursor can also be provided to the reaction chamber. During plasma power pulse 306, plasma power is applied to form a plasma (e.g., within the reaction chamber and/or remotely). Sequence 300 also include purge steps 308, 310, described in more detail below.

In some embodiments, the method for filling a gap comprises from at least 10 to at most 3000 deposition cycles, from at least 20 to at most 300 deposition cycles, or from at least 30 to at most 200 deposition cycles, or from at least 50 to at most 150 deposition cycles, or from at least 75 to at most 125 deposition cycles, for example 100 deposition cycles.

In some embodiments, the co-reactant is provided continuously, the precursor is provided in a plurality of precursor pulses, and the plasma is provided in a plurality of plasma pulses. Optionally, individual precursor pulses and individual plasma pulses are separated by purge steps.

In some embodiments, no gasses other than the precursor, the co-reactant, and a noble gas are introduced into the reaction chamber while introducing the precursor, the co-reactant and the plasma into the reaction chamber. In other cases, one or more dopant precursors can be provided to the reaction chamber—e.g., during one or more co-reactant and/or precursor pulses.

In some embodiments, introducing the precursor and the co-reactant occurs simultaneously or overlap.

In some embodiments, the co-reactant is provided continuously, the precursor is provided in a plurality of precursor pulses, the plasma is provided in a plurality of plasma pulses, and individual precursor pulses and individual plasma pulses are separated by purge steps.

In some embodiments, no gasses other than the precursor and the co-reactant are introduced into the reaction chamber during the steps of introducing the precursor, the co-reactant and the plasma into the reaction chamber. In some cases, one or more dopant precursors may be introduced to the reaction chamber.

In some embodiments, present methods include the use of a radio frequency (RF) plasma and make used of a cyclic deposition process employing pulsed precursor flow and a pulsed RF plasma (plasma power pulses). Preferably, the precursor pulses and the plasma power pulses are separated by purge gas pulses. Preferably, the co-reactant is used as a purge gas. In such embodiments, the desired aspects for flowability of depositing film include: 1) high enough partial pressure during the entire RF-on period for polymerization to progress; 2) sufficient energy to activate the reaction (defined by the RF-on period and RF power), during an RF period which is not too long; 3) temperature and pressure for polymerization/chain growth set above the melting point and below the boiling point of the flowable phase.

In some embodiments, the present methods involve providing the precursor intermittently to the reaction space, and continuously applying plasma power. In some embodiments, the present methods involve providing the precursor intermittently to the reaction space, and intermittently applying a plasma power. The latter embodiments thus feature the sequential application of precursor pulses and plasma power pulses to the reaction space. Preferably, the precursor pulses and the plasma power pulses are separated by purge gas pulses.

In some embodiments, the present methods involve providing the precursor continuously to the reaction space, and continuously or cyclically applying a plasma, e.g. through application of RF power, throughout the deposition step. The plasma may be continuous or pulsed, and it may be direct or remote.

In a preferred mode of operation, the flowable film is deposited by employing alternating precursor and plasma pulses.

In some embodiments, a pulsed plasma, e.g., a pulsed RF plasma power is applied. In some embodiments, the period of RF power application (i.e., the period in which co-reactants in the reactor are exposed to plasma) is in the range of at least 0.7 seconds to at most 2.0 seconds, for example from at least 0.7 seconds to at most 1.5 seconds.

In some embodiments, the deposition cycles comprise a sequence of a precursor pulse, a precursor purge, a plasma pulse, and a post plasma purge, which are continually repeated.

In some embodiments, the duration of the precursor pulse, i.e., the precursor feed time, is from at least 0.25 s to at most 4.0 s, or from at least 0.5 s to at most 2.0 s, or from at least 1.0 s to at most 1.5 s.

In some embodiments, the duration of the purge step (e.g., purge step 308) directly after the precursor pulse, i.e., the precursor purge time, is from at least 0.025 s to at most 2.0 s, or from at least 0.05 s to at most 0.8 s, or from at least 0.1 s to at most 0.4 s, or from at least 0.2 s to at most 0.3 s.

In some embodiments, the RF on time, i.e., the duration of a plasma pulse, that is the time during which RF power is provided during a plasma pulse, is from at least 0.5 s to at most 4.0 s, or from at least 0.7 s to at most 3.0 s, or from at least 1.0 s to at most 2.0 s, or from at least 1.25 s to at most 1.75 s, or of about 1.5 s.

In some embodiments, the post plasma purge time (e.g., purge step 310), i.e., the duration of the purge which occurs after application of a plasma pulse, is from at least 0.5 s to at most 10 s, from at least 1 s to at most 10 s, from at least 0.5 s to at most 2.0 s, or from at least 0.75 to at most 1.5 s, or from at least 0.9 to at most 1.1 s, for example 1.0 s.

In some embodiments, the methods are executed using a system comprising a precursor source which comprises a precursor recipient, e.g., a precursor canister, a precursor bottle, or the like. In such embodiments, the precursor recipient may be suitably maintained at a temperature which is from at least 5° C. to at most 50° C. lower than the temperature of the reaction chamber, or at a temperature which is from at least 5° C. to at most 10° C. lower than the temperature of the reaction chamber, or at a temperature which is from at least 10° C. to at most 20° C. lower than the temperature of the reaction chamber, or at a temperature which is from at least 30° C. to at most 40° C. lower than the temperature of the reaction chamber, or at a temperature which is from at least 40° C. to at most 50° C. lower than the temperature of the reaction chamber.

In some embodiments, a volatile precursor is polymerized within a certain parameter range mainly defined by partial pressure of precursor during a plasma strike, wafer temperature, and total pressure in the reaction chamber. In order to adjust the “precursor partial pressure,” an indirect process knob (dilution gas flow) may be used to control the precursor partial pressure. The absolute number of precursor partial pressure may not be required in order to control flowability of deposited film, and instead, a ratio of flow rate of precursor to flow rate of the remaining gas and the total pressure in the reaction space at a reference temperature can be used as practical control parameters. The above notwithstanding, and in some embodiments, the reaction chamber is maintained at a pressure of at least 600 Pa to at most 1200 Pa or at least 700 Pa to at most 1200 Pa.

In some embodiments, the present methods employing a plasma are executed in a reaction chamber that is maintained at a temperature of at least 50° C. to at most 75° C. This enhances the gap filling properties of the presently provided gap filling fluids.

In some embodiments, the substrate rests on a susceptor in the reaction chamber during the deposition cycles, and the susceptor temperature is from at least 50° C. to at most 100° C., or from at least 60° C. to at most 80° C., or from at least 65° C. to at most 75° C.

In some embodiments, the plasma is an RF plasma. In some embodiments, a plasma power of at least 10 W to at most 50 W is used for forming the gap filling fluid. In some embodiments, a plasma power of at least 10 W to at most 20 W is used for forming the gap filling fluid. In some embodiments, a plasma power of at least 20 W to at most 30 W is used for forming the gap filling fluid. In some embodiments, a plasma power of at least 30 W to at most 40 W is used for forming the gap filling fluid. In some embodiments, a plasma power of at least 40 W to at most 50 W is used for forming the gap filling fluid. In some embodiments, the RF power provided for flowable film deposition is from at least 50 W to at most 1000 W, or from at least 100 W to at most 900 W, or from at least 200 W to at most 800 W, or from at least 300 W to at most 700 W, or from at least 400 W to at most 600 W, or from at least 500 W to at most 550 W, or from at least 150 W to at most 300 W. It shall be understood that these powers are provided for the special case of 300 mm wafers. They can be readily converted to units of W/cm² to obtain equivalent RF power values for different wafer sizes.

In some embodiments, a plasma frequency of at least 40 kHz to at most 2.45 Ghz is used when the plasma is ignited in the reaction chamber, or a plasma frequency of at least 40 kHz to at most 80 kHz is used when the plasma is ignited in the reaction chamber, or a plasma frequency of at least 80 kHz to at most 160 kHz is used when the plasma is ignited in the reaction chamber, or a plasma frequency of at least 160 kHz to at most 320 kHz is used when the plasma is ignited in the reaction chamber, or a plasma frequency of at least 320 kHz to at most 640 kHz is used when the plasma is ignited in the reaction chamber, or a plasma frequency of at least 640 kHz to at most 1280 kHz is used when the plasma is ignited in the reaction chamber, or a plasma frequency of at least 1280 kHz to at most 2500 kHz is used when the plasma is ignited in the reaction chamber, or a plasma frequency of at least 2.5 MHz to at least 5 MHz is used when the plasma is ignited in the reaction chamber, or a plasma frequency of at least 5 MHz to at most 50 MHz is used when the plasma is ignited in the reaction chamber, or a plasma frequency of at least 5 MHz to at most 10 MHz is used when the plasma is ignited in the reaction chamber, or a plasma frequency of at least 10 MHz to at most 20 MHz is used when the plasma is ignited in the reaction chamber, or a plasma frequency of at least 20 MHz to at most 30 MHz is used when the plasma is ignited in the reaction chamber, or a plasma frequency of at least 30 MHz to at most 40 MHz is used when the plasma is ignited in the reaction chamber, or a plasma frequency of at least 40 MHz to at most 50 MHz is used when the plasma is ignited in the reaction chamber, or a plasma frequency of at least 50 MHz to at most 100 MHz is used when the plasma is ignited in the reaction chamber, or a plasma frequency of at least 100 MHz to at most 200 MHz is used when the plasma is ignited in the reaction chamber, or a plasma frequency of at least 200 MHz to at most 500 MHz is used when the plasma is ignited in the reaction chamber, or a plasma frequency of at least 500 MHz to at most 1000 MHz is used when the plasma is ignited in the reaction chamber, or a plasma frequency of at least 1 GHz to at most 2.45 GHz is used when the plasma is ignited in the reaction chamber. In exemplary embodiments, the plasma is an RF plasma, and RF power is provided at a frequency of 13.56 MHz.

In some embodiments, an electrode gap of at least 5 mm to at most 30 mm, e.g., an electrode gap of at least 5 mm to at most 10 mm, or an electrode gap of at least 10 mm to at most 20 mm, or an electrode gap of at least 20 mm to at most 30 mm when the plasma is ignited in the reaction chamber.

In some embodiments, the plasma exposure time is adjusted by changing the distance between upper and lower electrodes. Indeed, by increasing this distance, the retention time during which the precursor is retained in the reaction space between upper and lower electrodes is prolonged when the flow rate of precursor entering into the reaction space is kept constant. In some embodiments, the distance between the upper and lower electrodes is from at least 5.0 mm to at most mm, or from at least 10.0 mm to at most 25.0 mm, or from at least 15.0 mm to at most 20.0 mm.

In a further aspect, the presently described methods employ a thermally activated process for filling a gap with a gap filling fluid, e.g., to form a low-k dielectric. Such methods employ thermal energy instead of a plasma for forming a gap filling fluid. Such thermal methods comprise introducing a substrate in a reaction chamber. The reaction chamber comprises a susceptor and walls. The substrate is provided with a gap. The method further comprises placing the substrate on a susceptor comprised in the reaction chamber. A gas is then introduced into the reaction chamber. Suitable gasses include substantially inert gasses, i.e., gasses which do not substantially react with the precursor, such as N₂ and noble gasses such as He and Ar. The method further comprises introducing a precursor into the reaction chamber. In some embodiments, the inert gas may be a carrier gas employed to introduce the precursor into the reaction chamber, i.e., the inert gas may serve as a carrier gas. Alternatively, or additionally, the inert gas may be provided separately to the reaction chamber. The precursor consists of boron, nitrogen, and hydrogen. A suitable precursor is borazine, a derivative thereof, or a borohydride such as diborane. Also, the precursor has an activation temperature above which it polymerizes spontaneously, i.e. in a thermally activated fashion, and below which it is substantially stable. The method employing a thermally activated process further comprises maintaining the susceptor at a temperature which is higher than the activation temperature, and maintaining the walls at a temperature which is lower than the activation temperature. Thus, the precursor undergoes a thermally activated polymerization reaction in the vicinity of the susceptor, and forms a gap filling fluid that at least partially fills the gap. The gap filling fluid comprises boron, nitrogen, and hydrogen. Advantageously, the gap filling fluid substantially consists of boron, nitrogen, and hydrogen.

In some embodiments, the precursor as used in a thermal process can be represented by a chemical formula according to formula (a)

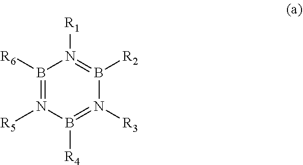

with R₁, R₂, R₃, R₄, R₅, and R₆ independently selected from H and a halogen. In some embodiments, at least one of R₁, R₂, R₃, R₄, R₅, and R₆ is F or Cl. Alternatively, R₁, R₂, R₃, R₄, R₅, and R₆ may all be H. Accordingly, in some embodiments, the precursor is borazine.

In a thermally activated process the susceptor may be maintained at a temperature of at least 80° C. to at most 150° C., or at a temperature of at least 80° C. to at most 100° C., or at a temperature of at least 100° C. to at most 120° C., or at a temperature of at least 120° C. to at most 150° C. Such temperatures can be suitable, for example, when borazine is used as a precursor.

In some embodiments, the methods are executed using a system comprising a precursor source which comprises a precursor recipient, e.g., a precursor canister, a precursor bottle, or the like. In such embodiments, the precursor recipient may be suitably maintained at a temperature which is from at least 5° C. to at most 50° C. lower than the temperature of the susceptor, or at a temperature which is from at least 5° C. to at most 10° C. lower than the temperature of the susceptor, or at a temperature which is from at least 10° C. to at most 20° C. lower than the temperature of the susceptor, or at a temperature which is from at least 30° C. to at most 40° C. lower than the temperature of the susceptor, or at a temperature which is from at least 40° C. to at most 50° C. lower than the temperature of the susceptor.

The embodiments described in the following paragraphs below may apply to the presently described methods employing a plasma and/or to the presently described methods that employ a thermal process.

In some embodiments, the co-reactant comprises nitrogen, hydrogen, ammonia, hydrazine, one or more noble gasses, and mixtures thereof. In some embodiments, the co-reactant comprises nitrogen and/or ammonia. In some embodiments, the co-reactant comprises a noble gas. In some embodiments, the noble gas is selected from the list consisting of He, Ne, Ar, and Kr. In some embodiments, the noble gas is Ar. In further cases, a dopant precursor can be provided during one or more deposition steps or pulses.

In some embodiments, all gases supplied to the reaction space throughout the present methods for filling a gap are the precursor, the co-reactant, an optional carrier such as N₂, Ar, and/or He, and an optional plasma ignition gas which can be or include Ar, He, N₂, and/or H₂, and an optional dopant precursor. In other words, no other gasses are provided to the reaction chamber than those listed, in these embodiments. In some embodiments, the carrier gas and/or the plasma ignition gas functions as a co-reactant.

In some embodiments, the co-reactant is a carrier gas. It shall be understood that a carrier gas refers to a gas that carries, or entrains, a precursor to the reaction chamber. An exemplary carrier gas includes a noble gas such as argon. Exemplary carrier gas flow rates are of at least 1 slm to at most 10 slm, or of at least 1 slm to at most 2 slm, or of at least 2 slm to at most 5 slm, or of at least 5 slm to at most 10 slm.

In some embodiments, the precursor has an activation temperature of at least 50° C. to at most 100° C., e.g. an activation temperature of at least 50° C. to at most 60° C., e.g., an activation temperature of at least 60° C. to at most 70° C., e.g. an activation temperature of at least 70° C. to at most 80° C., e.g. an activation temperature of at least 80° C. to at most 90° C., e.g., an activation temperature of at least 90° C. to at most 100° C.

In some embodiments, the reaction chamber in which the gap is filled is comprised in a system that in turn comprises a plurality of gas lines, a means for providing gasses such as precursors and co-reactants to the reaction chamber, such as one or more orifices, e.g. arranged as a showerhead, and a pump. The gas lines, the means for providing gasses to the reaction chamber, and the pump are maintained at a temperature lower than the activation temperature of the precursor, e.g., lower than a temperature of 70° C. or 80° C. Note that parts other than the reaction chamber comprised in the system may be suitably maintained at a temperature above the temperature of a precursor source comprised in the system, and below the activation temperature of the precursor. This can advantageously limit or prevent precursor condensation and precursor polymerization in parts of the reaction chamber where it is not desired, and thereby preventing precursor line clogging.

In some embodiments, the reaction chamber is comprised in a system that further comprises a cold trap. The cold trap can be suitably maintained at a temperature which is lower than a boiling temperature of the precursor. A cold trap may be placed, for example, in the reaction chamber or downstream from the reaction chamber. Accordingly, unreacted precursor can condense on the cold trap, and can thus be removed from the gas phase. A cold trap may be used as an alternative to a pump. Alternatively, a cold trap may be used in addition to a pump.

In some embodiments, the reaction chamber is maintained at a pressure of at least 500 Pa to at most 1500 Pa. In some embodiments, the reaction chamber is maintained at a pressure of at least 600 Pa to at most 1200 Pa or at least 700 Pa to at most 1200 Pa.

In some embodiments, the present methods are executed at a pressure of at least 500 Pa, preferably at a pressure of at least 700 Pa. More preferably, the present methods are executed at a pressure of at least 900 Pa. This is thought to enhance the gap filling properties of the presently provided gap filling fluids.

In some embodiments, the reaction chamber is maintained at a pressure of at least 500 Pa to at most 1500 Pa, and the reaction chamber is maintained at a temperature of at least 50° C. to at most 150° C. In some embodiments, the present methods are executed at a pressure of at least 500 Pa to at most 10,000 Pa and at a temperature of at least 50° C. to at most 200° C. In some embodiments, the present methods are executed at a pressure of at least 700 Pa and at a temperature of at least 50° C. to at most 150° C. In some embodiments, the present methods are executed at a pressure of at least 900 Pa, and at a temperature of at least 50° C. to at most 75° C.

The presently provided gap filling fluids can spontaneously solidify after deposition through recombination. Therefore, a separate curing step may not be necessary. Nevertheless, a curing step, e.g., a plasma or thermal curing step can be advantageous in order to improve one or more advantageous film properties such as resistance to shrinkage at high temperature and a low wet etch rate. The term “curing” can refer to a process of cross linking of as-deposited gap filling fluid oligomers, e.g. by means of a plasma such as a direct plasma or a remote plasma.

Thus, in some embodiments, the presently described methods comprise curing the gap filling fluid. This step increases the thermal resistance of the gap filling fluid. In other words, it increases the resistance of the gap filling fluid against deformation and/or mass loss at elevated temperatures. Additionally or alternatively, the curing step may cause the gap filling fluid to solidify.

Suitable plasma treatments include a direct or indirect H₂ plasma, a direct or indirect He plasma, a direct or indirect H₂/He plasma, a direct or indirect Ar plasma, a direct or indirect Ar/H₂ plasma, and a direct or indirect Ar/He/H₂ plasma. It shall be understood that a H₂ plasma refers to a plasma that employs H₂ as a plasma gas. Also, it shall be understood that a H₂/He plasma refers to a plasma that employs a mixture of H₂ and He as a plasma gas. It shall be understood that other plasmas are defined analogously.

In some embodiments, the step of curing involves the use of a noble gas plasma. In some embodiments, the noble gas plasma is a direct plasma. In some embodiments, the noble gas plasma is an indirect plasma.

Optionally, the gap filling fluid is subjected to an anneal after the gap filling fluid has been deposited and before the curing step. In some embodiments, an anneal is used as a curing step. Suitable annealing times include from at least 3.0 seconds to at most 10.0 minutes, for example from at least 20.0 seconds to at most 5.0 minutes, for example from at least 40.0 seconds to at most 2.5 minutes. Suitably, the anneal is performed in a gas mixture comprising one or more gasses selected from the list consisting of N₂, He, Ar, and H₂. Preferably, the anneal is carried out in an atmosphere that comprises N₂. In some embodiments, the anneal is carried out at a temperature of at least 200° C., or at a temperature of at least 250° C., or at a temperature of at least 300° C., or at a temperature of at least 350° C., or at a temperature of at least 400° C., or at a temperature of at least 450° C.

The step of curing may reduce the hydrogen concentration of the gap filling fluids. For example, the hydrogen concentration is reduced by at least 0.01 atomic percent to at most 0.1 atomic percent, or by at least 0.1 atomic percent to at most 0.2 atomic percent, or by at least 0.2 atomic percent to at most 0.5 atomic percent, or by at least 0.5 atomic percent to at most 1.0 atomic percent, or by at least 1.0 atomic percent to at most 2.0 atomic percent, or by at least 2.0 atomic percent to at most 5.0 atomic percent, or by at least 5.0 atomic percent to at most 10.0 atomic percent, or by at least 10.0 atomic percent to at most 20.0 atomic percent, or by at least 20.0 atomic percent to at most 30.0 atomic percent.

In some embodiments, the gap filling fluid is cured after it has been deposited. Additionally or alternatively, the gap filling fluid may be cured during deposition, e.g. by cyclically alternating deposition pulses and curing pulses.

In some embodiments, the step of curing involves the use of a direct plasma and the method for filling a gap comprises a plurality of cycles in which gap filling fluid deposition and plasma treatment steps are alternated. Thus, in some embodiments, the step of curing involves the use of a cyclic plasma treatment. When a cyclic plasma treatment is performed, deposition cycles and plasma curing cycles are alternated. The term “plasma curing cycle” refers to a plasma treatment step in which gap filling fluid is cured. In some embodiments, the cyclic plasma treatment involves the use of a gas mixture that does not comprise nitrogen.

A step of curing the gap filling fluid may involve, for example, the use of a direct plasma. When a direct plasma is used, a thin layer of gap filling fluid may be efficiently cured, yielding a thin high-quality layer. In some embodiments, especially when a thicker layer of cured gap filling fluid is desired, the method for filling a gap may comprise a plurality of cycles in which gap filling fluid deposition steps and curing steps employing a direct plasma treatment are alternated.

Thus, in some embodiments, the cyclic plasma treatment employs a direct plasma. In such embodiments, the process of filling a gap preferably comprises a plurality of cycles, i.e., plasma curing cycles, in which gap filling fluid deposition and plasma treatment steps are alternated. Such a cyclic process has the advantage that the a larger portion of the gap filling fluid is cured: a direct plasma typically has a penetration depth of around 2 to 7 nm, such that a post deposition direct plasma treatment would only cure a top layer of the gap filling fluid. Conversely, alternating deposition and plasma steps allows curing a larger part, or even the entirety of the gap filling fluid, even when using a curing technique such as a direct plasma which has a low penetration depth. In some cases, the treatment step may be performed after a number of 2 or more deposition steps.

In some embodiments, the cyclic plasma treatment involves the use of a noble gas such as Ar and/or He as a plasma gas.

In some embodiments, the step of curing involves the use of a micro pulsed plasma. A micro pulsed plasma is a plasma treatment that comprises the application of a plurality of rapidly succeeding on-off micro pulses. The micro pulsed plasma may, for example, employ a noble gas as a plasma gas. The micro-pulsed plasma may be a direct plasma or an indirect plasma. Advantageously, the micro-pulsed plasma is a direct plasma. When a 300 mm wafer is used as a substrate, a plasma gas flow rate of, for example, at least 5.0 slm, or of at least 5.0 slm to at most 7.0 slm, or of at least 7.0 slm to at most 10.0 slm is maintained during the micro pulsed plasma. For example, the on micro pulses in a micro pulsed plasma may last from at least 1.0 μs to at most 1.0 s, or from at least 2.0 μs to at most 0.50 s, or from at least 5.0 μs to at most 250 ms, or from at least 10.0 μs to at most 100.0 ms, or from at least 25.0 μs to at most 50.0 ms, or from at least 50.0 μs to at most 25.0 ms, or from at least 100.0 μs to at most 10.0 ms, or from at least 250.0 μs to at most 5.0 ms, or from at least 0.50 ms to at most 2.5 ms. For example, the off micro pulses in a micro pulsed plasma may last from at least 1.0 μs to at most 2.0 s, or from at least 2.0 μs to at most 1.0 s, or from at least 5.0 μs to at most 500 ms, or from at least 10.0 μs to at most 250.0 ms, or from at least 25.0 μs to at most 100.0 ms, or from at least 50.0 μs to at most 50.0 ms, or from at least 100.0 μs to at most 25.0 ms, or from at least 200.0 μs to at most 10.0 ms, or from at least 500.0 as to at most 5.0 ms, or from at least 1.0 ms to at most 2.0 ms. A micro pulsed plasma may be used cyclically and/or as a post-deposition treatment. In other words, a process of filling a gap may feature alternating cycles of gap filling fluid deposition and micro pulsed plasma. Additionally or alternatively, a micro pulsed plasma may be applied as a post-deposition treatment after all gap filling fluid has been deposited.

Preferably, a micro pulsed plasma is applied together with a plasma gas flow rate that is higher than a pre-determined threshold. The combination of a micro pulsed plasma with these high flow rates minimizes redeposition of volatile by products released during plasma-induced cross linking of the deposited gap filling fluid. In some embodiments, the flow rate of the plasma gas, e.g. N₂, H₂, NH₃, a noble gas, or a mixture thereof, during micro pulsed plasma treatment is at least 5.0 slm (standard liter per minute), preferably at least 10.0 slm. The skilled artisan understands that this flow rate depends on reaction chamber volume and substrate size, and the values provided here for 300 mm wafers and a reaction chamber volume of 1 liter can be readily transferred to other substrate sizes and/or reactor volumes. Preferably, a noble gas is used as a plasma gas during micro pulsed plasma treatment. In some embodiments, the noble gas is selected from the list consisting of He and Ar.

In some embodiments, the step of curing involves the use of a micro pulsed plasma involving the sequential application of a plurality plasma on and plasma off pulses. In some embodiments, a plasma gas flow rate of at least 5.0 slm is maintained during the micro pulsed plasma. Note that this flow rate is provided for a 300 mm wafer, and may be readily adapted for use with other wafer sizes.

In some embodiments, the step of curing involves the use of a remote plasma. In other words, in some embodiments, the step of curing involves the use of an indirect plasma. The radicals produced by remote plasmas feature a penetration depth which is significantly higher than the penetration length offered by direct plasmas, e.g. significantly higher than the size of the gaps to be filled by means of the presently provided methods. Consequently, a remote plasma treatment may be advantageously applied once after all the gap filling fluid has been deposited. This notwithstanding, a remote plasma cure may also be applied cyclically with alternating plasma cure and gap filling fluid deposition steps, similar to the operation with a direct plasma. The large penetration depths of remote plasmas has the advantage that they allow efficient curing of gap filling fluid. In some embodiments, the plasma gas employed in a remote plasma comprises a noble gas, for example a noble gas selected from the list consisting of He and Ar.

In some embodiments, the gap has a depth of at least 5 nm to at most 500 nm, or of at least 10 nm to at most 250 nm, or from at least 20 nm to at most 200 nm, or from at least 50 nm to at most 150 nm, or from at least 100 nm to at most 150 nm.

In some embodiments, the gap has a width of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the gap has a length of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the gap filling fluid extends into a particular gap for a distance that equals from at least 1.0 to at most 10.0 times the height of the gap. In some embodiments, the gap filling fluid extends into a particular gap for a distance that equals from at least 1.5 to at most 9.0 times the height of the gap. In some embodiments, the gap filling fluid extends into a particular gap for a distance that equals from at least 2.0 to at most 8.0 times the height of the gap. In some embodiments, the gap filling fluid extends into a particular gap for a distance that equals from at least 3.0 to at most 6.0 times the height of the gap. In some embodiments, the gap filling fluid extends into a particular gap for a distance that equals from at least 4.0 to at most 6.0 times the height of the gap. In some embodiments, the gap filling fluid extends into a particular gap for a distance that equals about 5.0 times the height of the gap.

In some embodiments, the substrate comprises a semiconductor.

In some embodiments, the method includes entirely filling the gap with a gap filling fluid. In some embodiments, the method includes filling the gap with gap filling fluid without the formation of voids. In other words, in some embodiments, the deposition according to the present methods is continued until the gap is fully filled with a material having filling capability, and substantially no voids are formed in the filled gap. The presence of voids can be observed by studying the formed material in a scanning transmission electron microscope.

In some embodiments, introducing the precursor and the co-reactant occurs simultaneously—e.g., the precursor, the co-reactant, and any dopant precursor can be in the reaction chamber at the same time.

In accordance with examples of the disclosure, a deposition rate of BN using a method described herein can be relatively high—e.g., greater than 1 nm/min (e.g., with an Ar carrier gas) or greater than 30 nm/min (e.g., with a nitrogen carrier gas).

In accordance with yet further examples of the disclosure, a silicon nitride cap can be deposited. The silicon nitride cap can mitigate degradation of the deposited (and optionally treated) BN. Exemplary process conditions for forming a SiN cap are provided below in table 4.

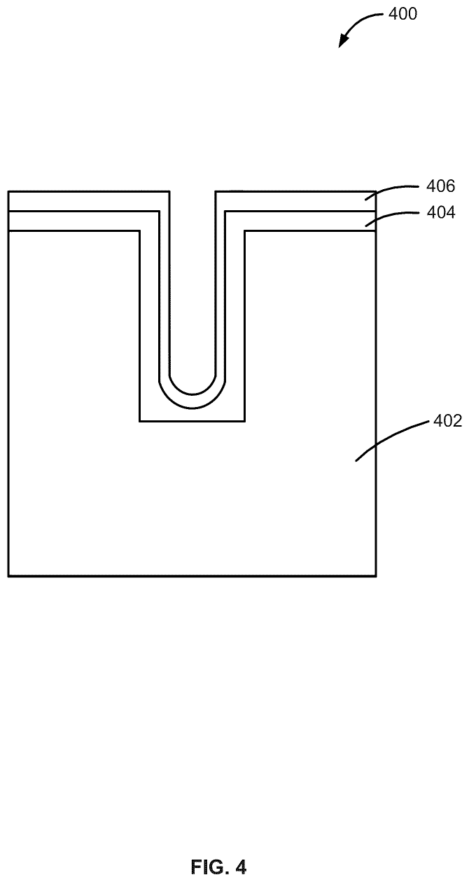

FIG. 4 illustrates a structure 400 in accordance with examples of the disclosure. Structure 400 includes a substrate 402 and a BN layer 404. BN layer can be formed according to a method described herein. In the illustrated example, structure 400 also includes a (e.g., SiN) cap layer 406. Use of cap layer 406 may be particularly useful when the co-reactant comprises nitrogen.

Further described is a system that is suitable for performing a method as disclosed herein. The system comprises one or more reaction chambers and a gas injection system fluidly coupled to at least one of the one or more reaction chambers. The system further comprises a first gas source for introducing a precursor and optionally a carrier gas in the reaction chamber. Suitable carrier gasses include gasses that may be used as a co-reactant, such as noble gasses, N₂, NH₃, H₂, etc. The system may further comprise a second gas source for introducing a mixture of one or more further gasses (e.g., a dopant precursor) into the reaction chamber. Or, the second gas source may be present, for example, when the carrier gas is different from the co-reactant. The system further comprises an exhaust for exhausting reaction products, carrier gas, and unused precursor and co-reactant and any dopant precursor. Also, the system comprises a controller. The controller is configured to control gas flow into the gas injection system and for causing the system to carry out a method as described herein.

In some embodiments, the system comprises a plasma generator, for example an RF generator for providing plasma power for generating a plasma in the reaction chamber. In such embodiments, the controller is further configured for causing the plasma generator to provide a plasma in the reaction chamber in accordance with the methods described herein.

In some embodiments, the gas injection system comprises a precursor delivery system that employs a carrier gas for carrying the precursor to one or more reaction chambers. In some embodiments, continuous flow of carrier gas is accomplished using a flow-pass system, wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and the precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching the main line and the detour line.

The skilled artisan will appreciate that the apparatus includes one or more controller(s) programmed or otherwise configured to cause the gap filling process described herein to be conducted. The controller(s) are communicated with the various power sources, heating systems, pumps, robotics, and gas flow controllers or valves of the reactor, as will be appreciated by the skilled artisan.

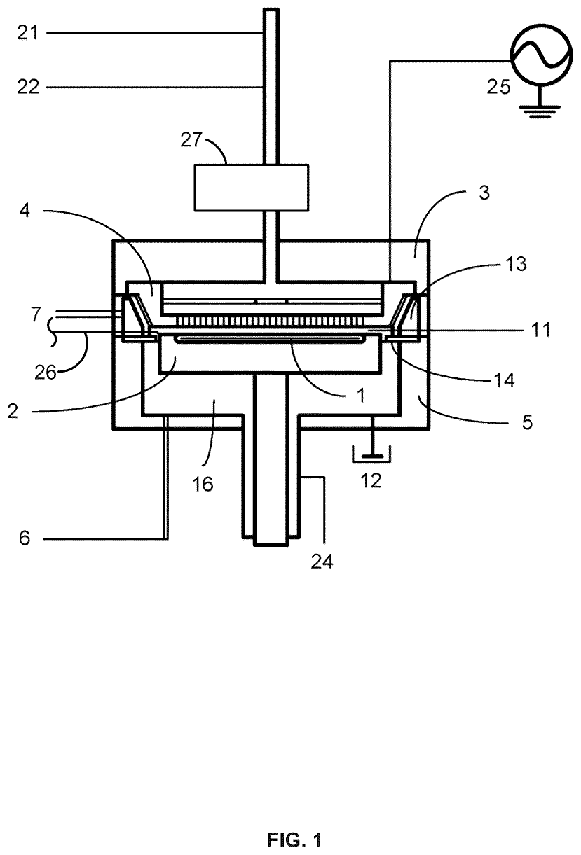

The presently provided methods may be executed in any suitable apparatus, including in a reactor as shown in FIG. 1. Similarly, the presently provided structures may be manufactured in any suitable apparatus, including a reactor as shown in FIG. 1. FIG. 1 is a schematic view of a plasma-enhanced atomic layer deposition (PEALD) apparatus, desirably in conjunction with controls programmed to conduct the sequences described below, usable in some embodiments of the present invention. In this figure, by providing a pair of electrically conductive flat-plate electrodes 2,4 in parallel and facing each other in the interior 11 (reaction zone) of a reaction chamber 3, applying RF power e.g. at 13.56 MHz and/or 27 MHz from a power source 25 to one side, and electrically grounding the other side 12, a plasma is excited between the electrodes. Of course, such a device may also be used for thermally forming a gap filling fluid to fill a gap in accordance with an embodiment of a method according to the present disclosure, in which case no RF power need be applied to any one of the electrodes (at least during the deposition process). A temperature regulator may be provided in a lower stage 2, i.e., the lower electrode. A substrate 1 is placed thereon and its temperature is kept constant at a given temperature. The upper electrode 4 can serve as a shower plate as well, and a co-reactant gas and/or a dilution gas, if any, as well as a precursor gas can be introduced into the reaction chamber 3 through a gas line 21 and a gas line 22, respectively, and through the shower plate or perforated plate 4. Additionally, in the reaction chamber 3, a circular duct 13 with an exhaust line 17 is provided, through which the gas in the interior 11 of the reaction chamber 3 is exhausted. Additionally, a transfer chamber 5 is disposed below the reaction chamber 3 and is provided with a gas seal line 24 to introduce seal gas into the interior 11 of the reaction chamber 3 via the interior 16 of the transfer chamber 5 wherein a separation plate 14 for separating the reaction zone and the transfer zone is provided. Note that a gate valve through which a wafer may be transferred into or from the transfer chamber 5 is omitted from this figure. The transfer chamber is also provided with an exhaust line 6. In some embodiments, the deposition of multi-element film and surface treatment are performed in the same reaction space, so that all the steps can continuously be conducted without exposing the substrate to air or other oxygen-containing atmosphere.

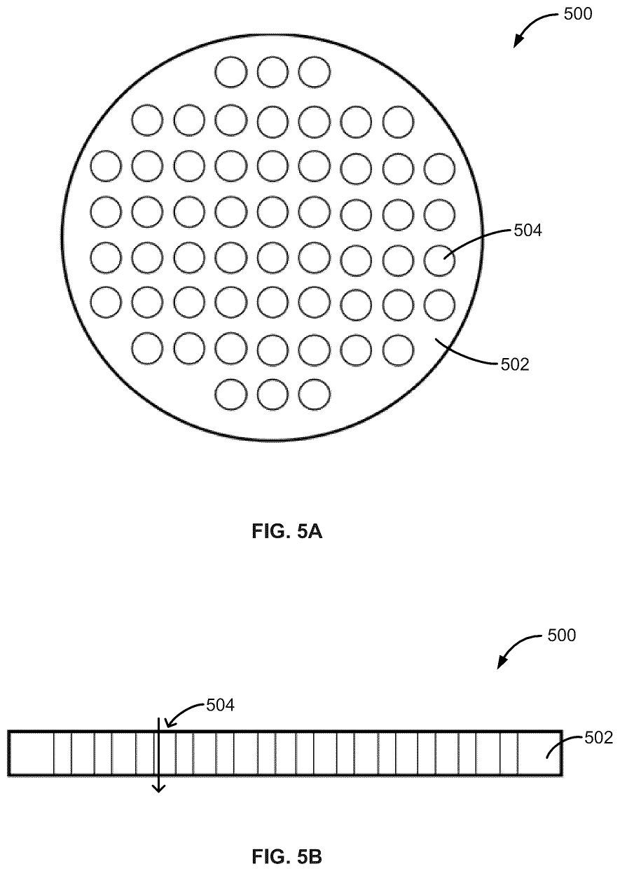

In some cases, a perforated plate 4 can be used to mitigate crystalline formation of BN during deposition. FIG. 5A illustrates a top and/or bottom view and FIG. 5B illustrates a side cross-sectional view of a perforated plate 500 for use as plate 4 in accordance with examples of the disclosure. Perforated plate 500 includes a plate 502 and a plurality of holes 504 therethrough. A direction of gas flow is indicated by the arrow in FIG. 5B. One or more of the precursor, the co-reactant, any dopant precursor, and any treatment gas can be flowed through perforated plate 500 during a method, such as a method described herein. In such cases, one or more of another of the precursor, co-reactant, any dopant precursor, and any treatment gas can be flowed through line 21, 22, or line 26. For example, radicals (e.g., formed using a co-reactant) from a remote plasma unit (e.g., RPU 27) can flow through the perforated plate 500 and a precursor can flow through line 26—or vice versa.

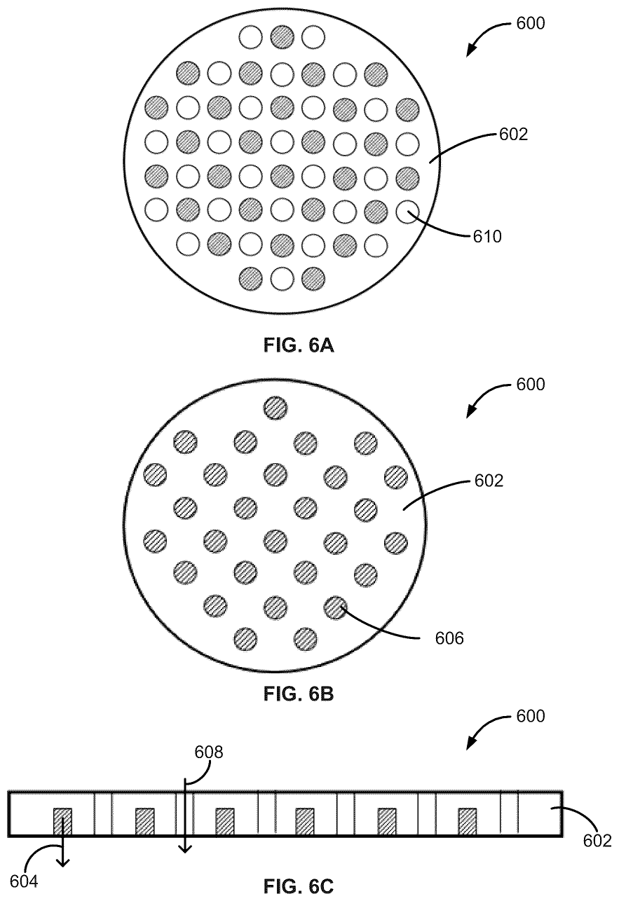

FIGS. 6A-6C illustrate a multichannel perforated plate 600 suitable for use as perforated plate 4. FIG. 6 A illustrates a top view, FIG. 6B illustrates a bottom view, and FIG. 6C illustrates a side cross-sectional view of multichannel perforated plate 600. In the illustrated example, perforated multichannel perforated plate 600 includes a plate 602, a first gas path 604 including holes 606 and a second gas path 608 including holes 610. First gas path 604 can be used to introduce one or more of the precursor, the co-reactant, any dopant precursor, and any treatment gas to a reaction chamber. Second gas path 608 can be used to provide another of one or more of the precursor, the co-reactant, any dopant precursor, and any treatment gas to a reaction chamber. Gasses from first gas path 604 and second gas path 608 can be separated until the gases exit multichannel perforated plate 600—e.g., within the reaction chamber. Lines 21, 22, and 26 can be used to introduce other gases, such as gases described herein. For example, radicals (e.g., formed using a co-reactant) from a remote plasma unit (e.g., RPU 27) can flow through first gas path 604 and/or line 26 (which can be coupled to RPU 27 or another RPU) and a precursor can flow through a line 21 and/or 22 or second gas path 608—or vice versa. In some cases, excited species may be flowed to the reaction chamber by flowing a treatment gas through RPU 27.

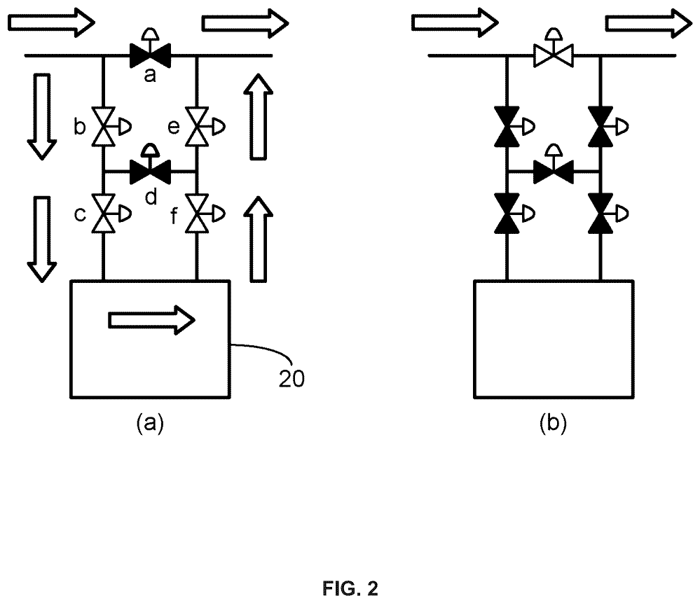

In some embodiments, the apparatus depicted in FIG. 1, the system of switching flow of a carrier gas and flow of a precursor gas illustrated in FIG. 2 can be used to introduce the precursor gas in pulses without substantially fluctuating pressure of the reaction chamber.

Indeed, a continuous flow of the carrier gas can be accomplished using a flow-pass system (FPS) wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching the main line and the detour line. FIG. 2 illustrates a precursor supply system using a flow-pass system (FPS) according to an embodiment of the present invention (black valves indicate that the valves are closed). As shown in (a) in FIG. 2, when feeding a precursor to a reaction chamber (not shown), first, a carrier gas such as Ar (or He) flows through a gas line with valves b and c, and then enters a bottle (reservoir) (20). The carrier gas flows out from the bottle (20) while carrying a precursor gas in an amount corresponding to a vapor pressure inside the bottle (20) and flows through a gas line with valves f and e and is then fed to the reaction chamber together with the precursor. In the above, valves a and d are closed. When feeding only the carrier gas (noble gas) to the reaction chamber, as shown in (b) in FIG. 2, the carrier gas flows through the gas line with the valve a while bypassing the bottle (20). In the above, valves b, c, d, e, and f are closed.

A skilled artisan will appreciate that the apparatus includes one or more controller(s) (not shown) programmed or otherwise configured to cause the deposition and reactor cleaning process described elsewhere herein to be conducted. The controller(s) are communicated with the various power sources, heating systems, pumps, robotics and gas flow controllers or valves of the reactor, as will be appreciated by the skilled artisan.

Optionally, a dual chamber reactor can be used. A dual chamber reactor comprises two sections or compartments for processing wafers disposed close to each other. In such a dual chamber reactor, a co-reactant gas and a noble gas can be supplied through a shared line and precursor-containing gases are provided by means of unshared lines. In exemplary embodiments, forming a gap filling fluid occurs in one of the two compartments, and the step of curing occurs in another reaction chamber. This can advantageously improve throughput, e.g. when gap filling fluid formation and curing occur at different temperatures.

Tables 1 and 2 illustrates exemplary deposition conditions in accordance with the disclosure. Table 3 provides exemplary conditions for a curing/treatment step. The exemplary conditions are provided for purpose of illustration and are not limiting.

TABLE 1

| | |
|---|---|
| Temp [° C.] | 400 |
| Precursor | Borazine |
| Pressure [Pa] | 700-1200 |
| Plasma | CCP 13.56 MHz Direct |
| Flow Ar [slm] | 0.5 |
| Flow H2 [slm] | 0.1-1.5 |
| Feed [s] | 0.1 |
| Feed Purge [s] | 0.1 |
| RF [s] | 1-3 |
| Post Purge [s] | 1 |
| Power [W] | 100-150 |

TABLE 2

| Depo Condition | Flow.Ar | Flow.N2 |
|---|---|---|
| Temp [° C.] | 50 | 50 |
| Gap [mm] | 7-15 | 12 |
| Pressure | 700-1800 | 700-1200 |
| Carrier [slm] | 0.5 Ar | 0.5 N2 |
| He [slm] | | 0.5 |
| Ar [slm] | 1-2 | 0.5 |
| N2 [slm] | | 0.5-1.5 |
| NH3 [slm] | 0.1-1 | 0.1-0.55 |
| Seal He [slm] | 1 | 1 |
| Feed [s] | 0.1 | 0.1 |
| Feed Purge [s] | 0.1 | 0.1 |
| RF [s] | 1-3 | 1-3 |
| Post Purge [s] | 1 | 1 |
| Power [W] | 100-300 | 150-300 |

TABLE 3

| | Flow.Ar |
|---|---|
| Temp [° C.] | 50 |
| Gap [mm] | 7 |
| Pressure | 500 |
| Ar Carrier [slm] | 0.5 |
| Ar [slm] | 0.5 |
| H2 [slm] | 0.5 |
| Seal He [slm] | 0.1 |
| RF [s] | 10-40 |
| Post Purge [s] | 20 |
| Power [W] | 500 |

Table 4 provides illustrative conditions for a silicon nitride cap deposition process.

TABLE 4
SiN Cap

| | |
|---|---|
| Temp [° C.] | 50 |
| Gap [mm] | 13 |
| Pressure | 300 |
| Carrier N2 [slm] | 0.3 |
| H2 [slm] | 0.5 |
| Ar [slm] | 1.8 |
| He [slm] | 1.5 |
| N2 [slm] | 0.4 |
| Seal He [slm] | 0.2 |
| Feed [s] | 0.2 |
| RF [s] | 2 |
| Power [W] | 35 |

As a further example, an exemplary curing step is discussed. The curing step may employ a continuous direct plasma for 20 seconds. Gap filling fluid deposition steps and this direct plasma curing step may be carried out cyclically, i.e. gap filling fluid deposition steps and curing steps may be executed alternatingly. This allows efficiently curing all, or at least a large portion, of the gap filling fluid. For curing gap filling fluid in gaps on a 300 mm substrate, each direct plasma curing step can feature, for example, 20 seconds of He plasma at an RF power of 200 W and a working pressure of 600 Pa. The reactor volume is ca. 1 liter and the He flow rate is 2 slm. Of course, the values given can be readily adapted for different substrate sizes without the exercise of inventive skill.

As a further example, another exemplary curing step is discussed. The curing step may involve the use of a micro pulsed plasma. In the present example, the curing step may be carried out cyclically, i.e. alternating cycles of gap filling fluid deposition and micro pulsed RF plasma are employed, though a post-deposition micro pulsed plasma curing treatment is possible as well. The application of cyclic gap filling fluid deposition and plasma steps allows efficiently curing all, or at least a large portion, of the gap filling fluid. For curing gap filling fluid in gaps on a 300 mm substrate, each direct curing step may feature 200 micropulses comprising 0.1 seconds of plasma on time and 0.5 seconds of plasma off time. The curing step may employ a He plasma at 400 Pa. The RF power provided may be 200 W. A He flow of 10 slm may be employed.

The present methods can be executed using, for example, a commercially available Eagle® XP8© PEALD system available from ASM® International.

The example embodiments of the disclosure described herein do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

What is claimed is:

1. A method of filling a gap comprising:
introducing in a reaction chamber a substrate provided with a gap;
introducing a precursor into the reaction chamber, the precursor consisting of boron, nitrogen, hydrogen, and optionally one or more halogens;
introducing a co-reactant into the reaction chamber; and
activating or fragmenting the precursor to form a gap filling fluid that at least partially fills the gap,
wherein the gap filling fluid solidifies to form deposited material, and
wherein a growth of the deposited material at a bottom of the gap is at least 1.5 times faster than a growth on sidewalls of the gap and on a top surface having the gap.

2. The method according to claim 1, wherein the precursor is represented by a chemical formula according to formula (i) 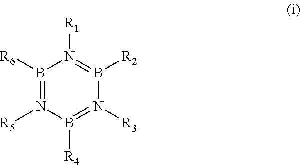
wherein at least one R₁, R₂, R₃, R₄, R₅, or R₆ is NH₂ or a halogen.

3. The method according to claim 2 wherein at least one of R₁, R₂, R₃, R₄, R₅, and R₆ is NH₂.

4. The method according to claim 1, wherein the precursor is borazine.

5. The method according to claim 1, wherein the reaction chamber is maintained at a temperature between 50° C. and 75° C.

6. The method according to claim 1, wherein the co-reactant is selected from Ar, He, a mixture of Ar and H₂, and a mixture of He and H₂.

7. The method according to claim 1, wherein the co-reactant is selected from Ar, He, and N₂.

8. The method according to claim 1, comprising a cyclic deposition process, wherein the co-reactant is provided continuously and wherein the precursor is provided in a plurality of pulses.

9. The method according to claim 1, wherein no gasses other than the precursor, the co-reactant, ammonia, nitrogen, and a noble gas are introduced into the reaction chamber while introducing the precursor, the co-reactant and the plasma into the reaction chamber.

10. The method according to claim 1, further comprising a step of providing a dopant precursor to the reaction chamber.

11. A method of filling a gap comprising:
introducing in a reaction chamber comprising a susceptor and walls, a substrate provided with a gap, and placing the substrate on the susceptor;
introducing an inert gas into the reaction chamber; and
introducing a precursor into the reaction chamber using a gas injection system,
wherein the gap filling fluid solidifies to form deposited material, and
wherein a growth of the deposited material at a bottom of the gap is at least 1.5 times faster than a growth on sidewalls of the gap and on a top surface having the gap.

12. The method according to claim 11 wherein the precursor comprises one or more of borazine or diborane.

13. The method according to claim 11, wherein the precursor is introduced into the reaction chamber by means of a carrier gas.

14. The method according to claim 13, wherein the carrier gas is selected from the list consisting of Ar, He, and N₂.

15. The method according to claim 11, further comprising a step of providing a dopant precursor to the reaction chamber.

16. The method according to claim 11, wherein the reaction chamber is comprised in a system, the system further comprising a plurality of gas lines, a showerhead, and a pump, wherein the gas lines, the showerhead, and the pump are maintained at a temperature lower than 70° C.

17. The method according to claim 11, wherein the reaction chamber is comprised in a system, the system further comprising a cold trap, wherein the cold trap is maintained at a temperature which is lower than a boiling temperature of the precursor.

18. The method according to claim 11, wherein the reaction chamber is at a pressure of at least 500 Pa to at most 1500 Pa.

19. The method according to claim 11, wherein the method includes entirely filling the gap with a gap filling fluid.

20. The method according to claim 11, further comprising curing the gap filling fluid.
